(19) United States
(12) Patent Application Publication
(10) Pub. No.: US 2022/0302327 A1
(43) Pub. Date: Sep. 22, 2022

(54) WAFER SOLAR CELL

(71) Applicant: HANWAH Q CELLS GMBH, Bitterfeld-Wolfen (DE)

(72) Inventor: Steffen GEISSLER, Bitterfeld-Wolfen (DE)

(21) Appl. No.: 17/634,862

(22) PCT Filed: Aug. 11, 2020
(86) PCT No.: PCT/DE2020/100698

§ 371 Date: Feb. 11, 2022

(30) Foreign Application Priority Data
Aug. 16, 2019 (DE) 10 2019 122 125.0

(51) Int. Cl. H01L 31/0224; H01L 31/02

(52) U.S. Cl. CPC H01L 31/022433; H01L 31/02008

(57) ABSTRACT

A wafer solar cell having a plurality of finger electrodes arranged on the surface of the solar cell, the electrodes extending in a direction of extent along the surface of the solar cell and have a width perpendicular to the direction of extent, wherein the width of each of the finger electrodes increases from that of the electrodes in a central region of the surface of the solar cell, viewed transversely to the direction of extent, to that of the finger electrodes in edge regions of the surface of the solar cell.

### RELATED APPLICATIONS

The present application is a National Phase entry of PCT Application No. PCT/DE2020/100698, filed Aug. 11, 2020, which claims priority to German Patent Application No. 10 2019 122 125.0, filed Aug. 16, 2019, the disclosures of which are hereby incorporated by reference herein in their entirety.

### FIELD OF THE INVENTION

The invention relates to a wafer solar cell. In particular, the invention relates to a wafer solar cell having a plurality of finger electrodes arranged on a solar cell surface, which extend in an extension direction along the solar cell surface and have a width perpendicular to the extension direction.

### BACKGROUND OF THE INVENTION

Such finger electrodes are typically applied by means of a screen printing method in a predetermined layout to the solar cell surface in such a way that they are often arranged on and/or in further structures such as previously generated laser contact openings or selective emitters of the wafer solar cell. However, screen printing processes vary, in the course of the service life of the screen used, in their accuracy in particular with respect to layout displacement, extension, pivoting, or the combination thereof in the submillimeter range. In the application of finger electrodes on the solar cell surface by means of screen printing, in particular layout elongations, i.e., a change in the size of the printed image, are observed in the course of the printing screen service life. The screen printing method having tolerances in the submillimeter range is to result in the predetermined layout, however, so that the finger electrodes overlap precisely fitted with the further structures located underneath in order to obtain a high-performance and cost-effective solar cell.

To compensate for observed layout changes in the screen printing method, widened finger structures can be used, which ensure a full overlap even in the event of certain displacements due to the wider dimensioning. Losses caused by layout displacement, pivoting, and/or distortion can thus be compensated for. However, this results in increased shading and thus a power loss of the wafer solar cell and an increased consumption of the costly screen printing pastes.

### SUMMARY

It is therefore an object of the invention to provide a wafer solar cell which has improved efficiency and/or performance and is producible easily and cost-effectively at the same time.

The object is achieved according to the invention by a wafer solar cell having the features of claim 1. Advantageous modifications and refinements are specified in the dependent claims.

The invention is based on the fundamental concept of providing a finger electrode structure design adapted to the unavoidable submillimeter changes of the screen print image. The inventors have established that a misalignment of the printed layout becomes greater with increasing distance to the center region of the printing screen: Finger electrodes arranged centrally on the solar cell surface are only affected relatively little by the layout distortion, while the finger electrodes arranged at the edge region are affected most strongly by the layout distortion. The layout of the finger electrodes generated by means of screen printing is optimized according to the invention on the basis of these findings obtained by process variation analyses.

According to the invention, the finger electrodes therefore have a respective width which increases starting from a center region of the solar cell surface, viewed transversely to the extension direction, toward the finger electrodes in edge regions of the solar cell surface. The layout distortion caused by the screen printing, such as layout displacement, stretching, pivoting, or the combination thereof is thus compensated for without the efficiency of the solar cell thus suffering and/or without resulting in increased shading losses and thus performance losses. The layout distortions occurring due to the screen printing are covered by the adapted finger electrodes. In particular, the respective width of the finger electrodes which are arranged in the center region is decreased and the respective width of the finger electrodes which are arranged in edge regions is increased or widened. No efficiency loss thus occurs due to shading and an increased consumption of a paste used to create the finger electrodes is avoided.

It is provided according to the invention that the respective width of the finger electrodes increases starting from a center region of the solar cell surface, viewed transversely to the extension direction, toward the finger electrodes in edge regions of the solar cell surface.

The center region in the meaning of the invention is a region around a center point of the wafer solar cell surface which preferably occupies 10% of the solar cell width and the solar cell height around the center point. The wafer solar cell preferably has a quadrilateral, in particular square solar cell surface at the time of the screen printing, wherein the corners can be rounded or chamfered.

The edge region in the meaning of the invention is a region which, starting from an edge of the solar cell surface, has a width which is preferably 10% of the solar cell width, wherein the solar cell width runs perpendicularly to the extension direction. The solar cell surface typically has two edge regions which extend in parallel to the extension direction of the finger electrodes and each have a width which runs perpendicularly to this extension direction. The edge regions extend to the left or right from the respective edge in parallel to the extension direction.

The finger electrodes can be arranged on a front side and/or rear side of the wafer solar cell. The front side of the solar cell is a side of the wafer solar cell on which light is directly incident.

In one preferred embodiment, the respective width of the finger electrodes increases, starting from the center region of the solar cell surface, toward the edge regions between 10% and 60%, preferably 15% to 55%, more preferably 20% to 50%. In particular, a sufficient accuracy and/or alignment of the finger electrodes on the further structures of the wafer solar cell are achieved using these value ranges.

The width of the finger electrodes arranged in the center region preferably has an absolute width in the range of 100 to 220 μm, preferably in the range of 110 to 170 μmore preferably 120 to 160 μm. That is to say, a width of the finger electrodes arranged in the edge region is in the range of 110 to 160 μm if the width of the finger electrodes arranged in the center region is 100 μm and varies in the range of 165 to 240 μm if the width of the finger electrodes arranged in the center region is 150 μm.

The increase in the width in different variants, preferably in the four following variants, can be designed in dependence on the predetermined layout:

In one preferred embodiment, the respective width of the finger electrodes increases, starting from the center region of the solar cell surface, toward the finger electrodes in the edge regions rising monotonously. That is to say, the respective width of the finger electrodes becomes greater and greater starting from the center region toward the edge region, wherein it can remain constant in sections, but never becomes less. In the monotonous relationship, the dimensions of the respective width tend to move, starting from the center region to the edge region, in the same relative direction, i.e., become greater but not necessarily at a constant rate. In the meaning of the invention, “monotonously rising” means that the respective width of the finger electrodes becomes greater and greater starting from the center region of the solar cell surface toward the edge regions, wherein it can remain constant in sections and the increase of the respective width can have a constant or inconstant rate.

Alternatively, the respective width of the finger electrodes preferably increases starting from the center region of the solar cell surface toward the finger electrodes in the edge regions in steps or stages. In the case of the increase in steps or stages, the respective width of the finger electrodes increases in stages or by stages.

Furthermore alternatively, the respective width of the finger electrodes preferably increases starting from the center region of the solar cell surface toward the finger electrodes in the edge regions rising linearly. The linearly rising increase of the respective width is modeled by a linear increase of the respective widths of adjacent finger electrodes via the parameter of the increasing distance to the center of the solar cell. This linear increase is implemented at a constant rate. The linearly rising increase of the respective width comprises the monotonously rising increase.

Furthermore alternatively, the respective width of the finger electrodes preferably increases starting from the center region of the solar cell surface toward the finger electrodes in the edge regions rising via a nonlinear functional relationship having the parameter of the increasing distance to the center of the solar cell. In one preferred embodiment, the respective width of each finger electrode is constant along the extension direction.

Alternatively preferably, the respective width of one or more finger electrodes tapers starting from ends of these finger electrodes along the extension direction toward the respective center of these finger electrodes. A greater width of the finger electrodes in the region of their ends is thus provided. In the event of a pivot of the printing screen relative to the surface to be printed, it can thus be ensured that the overlap of the structures to be covered is also ensured in the edge regions of the finger electrodes. The upper and the lower edge region each extend between the left edge region and the right edge region. They each have a width which extends in parallel to the extension direction and is preferably 10% of the solar cell width. The finger electrodes extend in the extension direction along the solar cell surface starting from the upper edge region to the lower edge region or vice versa.

The finger electrodes which are arranged in the center region are preferably designed having a respective width which tapers, starting from ends of these finger electrodes, along the extension direction toward the respective center of these finger electrodes.

In one preferred embodiment, the respective width of the one or more finger electrodes tapers starting from the ends of this finger electrode in the direction toward the respective center of this finger electrode monotonously decreasing. That is to say, the respective width of the one or more finger electrodes becomes less and less starting from their ends toward the center, wherein it can remain constant in sections but never becomes greater. In this monotonous relationship, the respective width tends to move starting from the ends of this finger electrode in the direction toward the respective center of this finger electrode in the same relative direction, but not necessarily at a constant rate.

In one refinement of the monotonous decrease of the absolute width of the finger electrodes, the respective width of the one or more finger electrodes tapers in steps or stages starting from the ends of this finger electrode in the direction toward the respective center of this finger electrode. In the decrease in steps or stages, the respective width of the finger electrodes decreases in stages or by stages.

The respective width of the one or more finger electrodes particularly preferably tapers starting from the ends of this finger electrode in the direction toward the respective center of this finger electrode linearly decreasing. The linearly decreasing tapering is modeled by a linear decrease starting from the ends of this finger electrode in the direction toward the respective center of this finger electrode which is implemented at a constant rate.

Furthermore alternatively, the respective width of the one or more finger electrodes preferably tapers starting from the ends of this finger electrode in the direction toward the respective center of this finger electrode non-linearly decreasing.

The respective width of the one or more finger electrodes preferably decreases from the ends toward the respective center between 20% to 50%, preferably between 25% to 45%, more preferably 30% to 40%. In this case, the respective width of the one or more finger electrodes can taper monotonously decreasing, in steps or stages, linearly decreasing, or nonlinearly decreasing. In particular, the width of the ends of the one or more finger electrodes is between 20% to 50%, preferably between 25% to 45%, more preferably 30% to 40% greater than the width of the center of the corresponding finger electrode.

In one preferred embodiment, the wafer solar cell has one or more busbars running transversely to the extension direction. The respective width of the one or more finger electrodes preferably tapers starting from the ends of this finger electrode in the direction toward the respective center of this finger electrode via an interruption by the busbar or busbars.

The finger electrodes are preferably arranged on and/or in laser contact openings. The laser contact openings are preferably introduced in a further predetermined layout into the solar cell surface. Laser contact openings are openings which are introduced by means of a laser into the solar cell surface. They are used to establish an electrical contact between the finger electrodes and structure elements located on a side of the solar cell surface which is opposite to the side on which the finger electrodes are arranged. Both laser processes and printing processes display variations in their positioning accuracy, above all over the service life of the printing screens. The design according to the invention of the finger electrodes counteracts the disadvantages accompanying this.

The wafer solar cell is preferably designed as a PERC (Passivated Emitter and Rear Contact or Passivated Emitter Rear Cell) solar cell. In PERC technology, a dielectric layer is integrated into the solar cell structure, which is processed by a laser and thus provided with the laser contact openings. This dielectric layer reflects the light in the solar cell which has penetrated to the rear side without generating charge carriers. A further possibility for generating charge carriers is provided in this way.

In one preferred embodiment, the wafer solar cell is designed as a bifacial solar cell. A bifacial solar cell is a solar cell which can use incident light not only via its front side, but also via its rear side. When the bifacial solar cell is installed in a solar module, indirect light due to reflected sunbeams can reach the solar cell from the rear and be utilized thereby. In this way, the solar module achieves a higher efficiency.

The bifacial solar cell preferably has laser contact openings and finger electrodes on the rear side. The finger electrodes are preferably made of aluminum. Alternatively, the finger electrodes are preferably made of silver.

### BRIEF DESCRIPTION OF THE DRAWINGS

Two preferred exemplary embodiments of the invention are illustrated by way of example in the figures and will be described in more detail hereinafter. In the figures, which are solely schematic and are not to scale:

FIG. 1 shows a partial top view of a wafer solar cell according to the invention; and

FIG. 2 shows a top view of a further wafer solar cell according to the invention.

### DETAILED DESCRIPTION

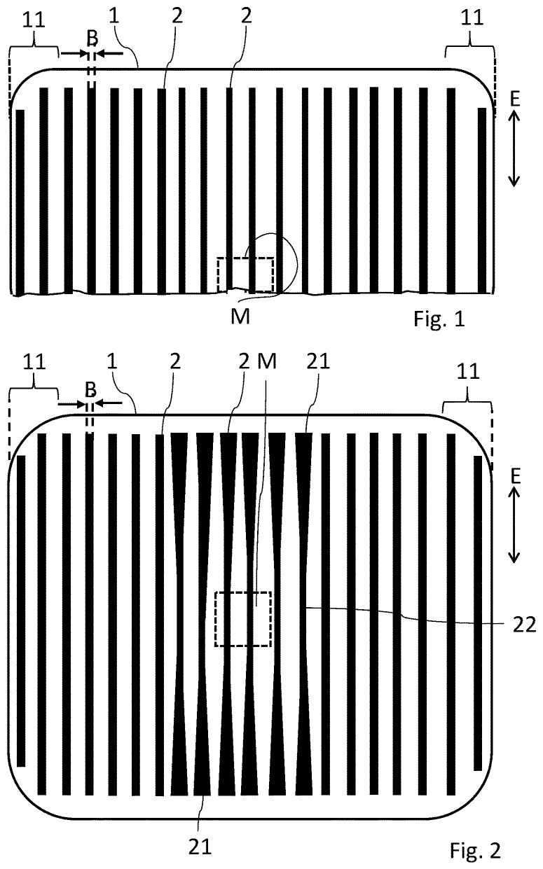

FIG. 1 shows a partial top view of a wafer solar cell according to the invention. The wafer solar cell has a solar cell surface 1 and a plurality of finger electrodes 2. The finger electrodes 2 are arranged on the solar cell surface 1 and extend in parallel to one another in an extension direction E along the solar cell surface 1. The finger electrodes 2 each have a width B perpendicular to the extension direction E, which is constant in each case along the extension direction E. The respective width B of the finger electrodes 2 increases, starting from a center region M of the solar cell surface 1 viewed transversely to the extension direction E, toward the finger electrodes 2 in edge regions 11 of the solar cell surface 1.

The center region M is a region which, starting from the center point (not shown) of the solar cell surface 1, occupies 10% of the solar cell width. Each edge region 11 is a region which, starting from an edge (not shown) of the solar cell surface 1, has a width which is 10% of the solar cell width. The solar cell surface 1 has two edges which extend in parallel to the extension direction E and have a width which runs perpendicularly to the extension direction E. In FIG. 1, the edge region 11 located on a left side of the solar cell surface 1 and the edge region 11 located on a right side of the solar cell surface 1 are shown.

FIG. 2 shows a top view of a further wafer solar cell according to the invention. The wafer solar cell shown in FIG. 2 corresponds to the wafer solar cell shown in FIG. 1 with the difference that the respective width B of multiple finger electrodes 2 tapers, starting from ends 21 of these finger electrodes 2 along the extension direction E of the finger electrodes 2, toward the respective center 22 of these finger electrodes 2. The change of the absolute width B of the finger electrodes 2 is shown exaggerated here and not to scale. The multiple finger electrodes 2—six solely by way of example—tapering from their ends 21 toward their center 22 are arranged in particular in the center region M and adjacent thereto and to one another. Preferably, all finger electrodes 2 are formed having such a width B tapering toward the respective center 22. However, this variant is not shown in FIG. 2.

### LIST OF REFERENCE SIGNS

B width
E extension direction
M center region
1 solar cell surface
11 edge region
2 finger electrode
21 end
22 center

1. A wafer solar cell, comprising:
a plurality of finger electrodes arranged on a solar cell surface, which extend in an extension direction along the solar cell surface and have a width perpendicular to the extension direction,
wherein the respective width of the finger electrodes increases, starting from a center region of the solar cell surface viewed transversely to the extension direction, toward the finger electrodes in edge regions of the solar cell surface.

2. The wafer solar cell as claimed in claim 1, wherein the respective width of the finger electrodes increases, starting from the center region of the solar cell surface toward the edge regions, between 10% and 60%.

3. The wafer solar cell as claimed in claim 1, wherein the width of the finger electrodes arranged in the center region has an absolute width in the range of 100 to 220 μm.

4. The wafer solar cell as claimed in claim 1 wherein the respective width of the finger electrodes increases, starting from the center region of the solar cell surface toward the finger electrodes in the edge regions , monotonously rising, rising in steps or stages, linearly rising, or nonlinearly rising.

5. The wafer solar cell as claimed in claim 1 wherein the respective width of each finger electrode is constant along the extension direction.

6. The wafer solar cell as claimed in claim 1 wherein the respective width of one or more finger electrodes tapers, starting from ends of these finger electrodes along the extension direction, toward the respective center of these finger electrodes.

7. The wafer solar cell as claimed in claim 6, wherein the respective width of the one or more finger electrodes tapers, starting from the ends of this finger electrode in the direction toward the respective center of this finger electrode, monotonously decreasing, decreasing in steps or stages, linearly decreasing, or nonlinearly decreasing.

8. The wafer solar cell as claimed in claim 6, wherein the respective width of the one or more finger electrodes decreases from the ends toward the respective center between 20% to 50%.

9. The wafer solar cell as claimed in claim 6, wherein the wafer solar cell further comprises one or more busbars running transversely to the extension direction and the respective width of the one or more finger electrodes tapers, starting from the ends of this finger electrode in the direction toward the respective center of this finger electrode, via an interruption by the busbar or busbars.

10. The wafer solar cell as claimed in claim 1 wherein the finger electrodes are arranged on, and/or in, laser contact openings.

11. The wafer solar cell as claimed in claim 2, wherein the respective width of the finger electrodes increases, starting from the center region of the solar cell surface toward the edge regions between 15% to 55%,

12. The wafer solar cell as claimed in claim 11, wherein the respective width of the finger electrodes increases, starting from the center region of the solar cell surface toward the edge regions between 20% to 50%.

13. The wafer solar cell as claimed in claim 3, wherein the width of the finger electrodes arranged in the center region has an absolute width in the range of range of 110 to 170 μm.

14. The wafer solar cell as claimed in claim 13, wherein the width of the finger electrodes arranged in the center region has an absolute width in the range of range of 120 to 160 μm.

15. The wafer solar cell as claimed in claim 8, wherein the respective width of the one or more finger electrodes decreases from the ends toward the respective center between 25% to 45%.

16. The wafer solar cell as claimed in claim 15, wherein the respective width of the one or more finger electrodes decreases from the ends toward the respective center between 30% to 40%.
